(19) United States
(12) Patent Application Publication
(10) Pub. No.: US 2025/0212495 A1
(43) Pub. Date: Jun. 26, 2025

(54) METHOD FOR FORMING A SEMICONDUCTOR STRUCTURE

(71) Applicants: IMEC VZW, Leuven (BE); TOKYO ELECTRON LIMITED, Tokyo (JP)

(72) Inventors: Boon Teik Chan, Wilsele (BE); Steven Demuynck, Aarschot (BE); Efrain Altamirano Sanchez, Kessel-Lo (BE); Alfonso Sepulveda Marquez, Leuven (BE); Masafumi Ishida, Nirasaki-city (JP)

(21) Appl. No.: 18/987,560

(22) Filed: Dec. 19, 2024

(30) Foreign Application Priority Data
Dec. 22, 2023 (EP) 23220073.3

(51) Int. Cl. H10D 84/01; H01L 21/02; H01L 21/306; H10D 62/00; H10D 62/832

(52) U.S. Cl. CPC H10D 84/0188; H01L 21/0214; H01L 21/02274; H01L 21/30604; H10D 62/021; H10D 62/832; H10D 84/0167; H10D 84/017; H10D 84/0172

(57) ABSTRACT

The present disclosure provides a method for forming a semiconductor structure. The method includes forming a layer stack on a substrate. The layer stack includes a first sub-stack, a second sub-stack on the first sub-stack and includes a plurality of sacrificial layers alternating between first and second sacrificial layers, and a third sub-stack on the second sub-stack. The method includes forming recesses in the first sacrificial layers, removing the at least one second sacrificial layer, depositing dielectric material in the at least one cavity, and depositing dielectric material in the recesses of the first sacrificial layers, wherein at least one of the acts of depositing dielectric material in the at least one cavity, and depositing dielectric material in the recesses of the first sacrificial layers, is performed by a first chemical vapor deposition method, CVD method.

### CROSS-REFERENCE TO RELATED APPLICATIONS

The present application is a non-provisional patent application claiming priority to European Patent Application No. 23220073.3, filed Dec. 22, 2023, the contents of which are hereby incorporated by reference.

### FIELD OF THE DISCLOSURE

The present disclosure relates to a method for forming a semiconductor structure.

### BACKGROUND

Complementary FETs (CFETs) are on the scaling roadmap as one of the next generation scaling options. The CFET comprises a NFET (e.g., a N-type FET) and a PFETR (e.g., a P-type FET) stacked on top of each other (or the reverse). The NFET and the PFET are separated vertically by a middle dielectric isolation (MIDI) and the bottom device can also be isolated from the substrate by a bottom dielectric isolation (BDI).

### SUMMARY

The present disclosure provides a semiconductor structure and/or a production method for the same.

An example embodiment provides a method for forming a semiconductor structure having comparably less processing steps.

An example embodiment provides a stable semiconductor structure with improved electrical performance.

According to an example embodiment, there is provided a method for forming a semiconductor structure. The method comprises forming a layer stack on a substrate. The layer stack comprises a first sub-stack comprising a first sacrificial layer and on the first sacrificial layer a channel layer providing (e.g., defining) a topmost layer of the first sub-stack. The layer stack also comprises a second sub-stack on the first sub-stack and comprising a plurality of sacrificial layers alternating between first and second sacrificial layers, wherein neighboring first and second sacrificial layers of the second sub-stack are separated by a liner layer, and wherein first sacrificial layers may provide (e.g., define) a respective bottommost and topmost layer of the second sub-stack. The second sub-stack comprises at least one second sacrificial layer. The layer stack further includes a third sub-stack on the second sub-stack and comprising a channel layer providing (e.g., defining) a bottommost layer of the third sub-stack and a first sacrificial layer on the channel layer. The first sacrificial layers are formed of a first sacrificial semiconductor material, the second sacrificial layers are formed of a second sacrificial semiconductor material different from the first sacrificial semiconductor material, and the liner layers are formed of a semiconductor material different from the first and second semiconductor materials. The method also includes forming source/drain recesses, the source/drain recesses exposing end surfaces of the layer stack, forming recesses in the first sacrificial layers of the layer stack by laterally etching back the end surfaces of the first sacrificial layers from opposite ends of the layer stack, by selective etching, removing the at least one second sacrificial layer of the second sub-stack by (e.g., selective) etching, thereby forming at least one cavity, while the first sacrificial layers of the second sub-stack are being protected from vertical etching by the liner layers, depositing dielectric material in the at least one cavity, and depositing dielectric material in the recesses of the first sacrificial layers. At least one of the acts of depositing dielectric material in the at least one cavity and depositing dielectric material in the recesses of the first sacrificial layers is performed by a first chemical vapor deposition (CVD) method. The first CVD method comprises reacting, as a film-forming gas, an oxygen-containing silicon compound gas with a non-oxidizing hydrogen-containing gas in a state in which at least the non-oxidizing hydrogen-containing gas is plasmarized, to form a film of a flowable silanol compound, and, subsequently, annealing the film of flowable silanol compound into the first dielectric material. The oxygen-containing silicon compound gas comprises Si_{α}O_{β}(O—CₘHₙ)_{Γ}CₓH_{y}, wherein m, n, and a are integers of 1 or more, and wherein β, Γ, x, and y are integers of 0 or more; and β and Γ are not 0 at the same time.

The wording “a first layer arranged on a second layer” may reference any of the layers (e.g., or layers of the sub-stack) of the layer stack and hereby provides that the first layer is arranged (e.g., directly) on (e.g., in abutment with) the second layer.

Relative spatial terms such as “topmost,” “bottom,” “lower,” “vertical,” “stacked on top of,” herein denote locations or directions within a frame of reference of the semiconductor structure. In an example embodiment, the terms may be in relation to a normal direction of the substrate on which the layer stack is formed, or equivalently in relation to a bottom-up direction of the layer stack. Correspondingly, terms such as “lateral” and “horizontal” are locations or directions parallel to the substrate.

The term “thickness” may refer to a dimension of a structure (e.g., a layer of a sub-stack) as seen along a normal to a surface underlying the structure (e.g., the layer of the sub-stack). For example, the thickness of a layer of the layer stack, or the thickness of the sub-stack, may refer to the thickness dimension of the layer/sub-stack as seen along the bottom-up direction of the layer stack.

The semiconductor structure may be a semiconductor structure for producing a stack of field effect transistors (FETs) comprising a top and bottom FET. The stack of FETs may be CFET, wherein the top FET is a NFET and the bottom FET is a PFET, or vice versa. Thus, the semiconductor structure may be a semiconductor structure suitable to be converted into a stack of FETs, such as a CFET.

Accordingly, the method is compatible with Complementary FET (CFET) device fabrication. The method is also compatible with forksheet device fabrication. The resulting semiconductor structure may be used to produce a stack of FETs.

The layer stack may (e.g., sometimes) be referred to as a superlattice stack.

When opposite ends of the layer stack are referred to herein, the opposite ends may be the end where source/drain regions are to be formed.

Channel layers of the first sub-stack may be channel layers for a bottom FET. Similarly, channel layers of the third sub-stack may be channel layers for a top FET. Channel layers may be Si layers.

First sacrificial layers may be layers that can be replaced with a gate stack during production of a stack of FETs.

Second sacrificial layers are layers that are replaced with dielectric material during production of a stack of FETs. The dielectric material may then function as electrical isolation between the bottom and top FET. Such electrical isolation between the bottom and top FET may be referred to as middle dielectric isolation.

The liner layers may be layers resistant to the etchant used to etch the second sacrificial layers. The liner layers may be layers resistant to the etchant used to recess the first sacrificial layers. The liner layers may be thin (e.g., thinner than the first and second sacrificial layers).

As mentioned herein, the first and second sacrificial layers are formed of different semiconductor materials. Thus, etchants may have different etch rates for the first and second sacrificial layers. Thus, the first and second sacrificial layers may be (e.g., selectively) etched at different points in the production process, or should they be etched at the same time, the first and second sacrificial layers may be etched a different amount. The channel layers, liner layers, first sacrificial layers, and second sacrificial layers may (e.g., all) be of different materials. Alternatively, channel layers and liner layers may be formed of the same material, different from the first and second sacrificial semiconductor materials. In an example embodiment, channel layers and liner layers are formed of Si and the first and second sacrificial layers are formed of SiGe, wherein the first and second sacrificial layers have different Ge compositions.

The dielectric material deposited in the at least one cavity may form a respective layer of MDI.

The dielectric material may be a nitride, such as SiN. The dielectric material may be conformally deposited (e.g., by ALD) with a thickness (e.g., sufficient) to fill (e.g., and pinch-off) the respective cavity. Examples of a dielectric material include SiO₂, Si₃N₄, SiCO, SiOCN, SiON, SiCN, SiC, SiBCN, and SiBCNO.

The dielectric material that is deposited in the recesses of the first sacrificial layers may form inner spacers. The term “inner spacers” hereby discloses dielectric layer portions formed in the recesses to cover end surfaces of the first sacrificial layers. Forming the inner spacers may comprise conformally depositing an inner spacer material layer. Forming the inner spacers may comprise (e.g., subsequently) etching the inner spacer material layer such that a discrete portion of the inner spacer material layer remains in each recess to form an inner spacer therein. The spacer material may, in an example embodiment, be etched using an isotropic etching process. An isotropic etching process provides (e.g., allows) the inner spacer material layer to be etched at a (e.g., substantially) uniform rate. Hence, the structures covered by the inner spacer material layer may remain covered from the etchants by the inner spacer material layer (e.g., substantially) until the channel layer end surfaces are exposed, wherein the etching may be stopped. The inner spacer material layer may be deposited with a thickness such that the recesses are pinched-off (e.g., closed).

The term “conformally depositing” may refer to a deposition process resulting in a conformally grown layer or film. Conformal deposition may be provided using an atomic layer deposition (ALD) process.

Any deposition steps, such as forming dielectric layers and inner spacers, may alternatively be formed with the first CVD method. When the first CVD method is compared to conventional methods, such ALD, the usefulness of the disclosure herein will be apparent.

The first CVD process is described in US20220235456A1, which is hereby incorporated by reference. In an example embodiment, the detailed description of US20220235456A1 is incorporated by reference.

The first CVD method may be called Ultra Chemical Vapor Deposition (UCVD) or Chemical Vapor Liquid Deposition. In the description herein, the term UCVD may (e.g., primarily) be used.

The UCVD method provides usefulness.

The UCVD method may (e.g., primarily) deposit material in cavities and/or trenches. Thus, the dielectric material may (e.g., primarily) be deposited in the cavity formed by removing the second sacrificial layer and/or in the recesses. The dielectric material deposited by the UCVD method may have a flat profile.

It may be noted that flat profiles are generally used to provide (e.g., mean) that end surfaces of the dielectric material may have little or no rounding. The rounding of corners of the end surfaces may (e.g., sometimes) be referred to as curving. The provision of such flat profile dielectric material may provide (e.g., enable) a reduction of processing steps since separate steps such as pre-cleaning may not be used (e.g., needed). The reduction of pre-cleaning steps may provide (e.g., enable) a reduction of erosion of the dielectric layers/sacrificial layer, or any other layers of the layer stack that would (e.g., normally) be subjected to erosion.

Further, the UCVD method may provide a dielectric material compound with few voids (e.g., void free dielectric material) and thereby there may be provided (e.g., high quality) dielectric material.

The formation of the recesses in the first sacrificial layers and the removal of the at least one second sacrificial layer is performed by etching. The liner layers are (e.g., particularly important) as the liner layers may protect the interface between first and second sacrificial layers during the etch. Thus, the liner layer may be a layer resistant to the etchant used to etch, e.g., the second sacrificial layers. The liner layers may be thin, e.g., thinner than the first and second sacrificial layers. Thus, the liner layers may protect the interface between first and second sacrificial layers while at the same time contributing little or not at all to the strain in the layer stack.

The liner layers may protect the interface between the first and second sacrificial layers such that any erosion of the first and second sacrificial layers may be prevented, or at least reduced. Such an erosion could (e.g., normally) result in undesirable profiles, e.g., curving of end surfaces, of the first and second sacrificial layers which in turn would hamper the ability to form (e.g., high-quality) dielectric layers in the layer stack. The provision of liner layers may thus facilitate the formation of high-quality dielectric layers which in turn results in a semiconductor structure with improved electrical performance.

The liner layers do not necessarily only provide protection for the first and second sacrificial layers. The liner layers may provide protection and thereby reduce erosion of the remaining layers of the layer stack, such as the channel layers.

Also, the use (e.g., employment) of liner layers in combination with deposition performed by the UVCD method may together contribute to even higher quality dielectric layers.

Although the method may in an example embodiment be used in conjunction with forming forksheet and CFET devices, the method may be used also to form other horizontal channel FET devices (e.g., nanowire FETs (NWFETs) or as discussed above, nanosheet FETs (NSHFETs)) using (e.g., requiring) inner spacers, and which may benefit from liner layers.

The term “layer stack” hereby provides a structure of layers, sequentially formed on top of each other. The layer stack may in an example embodiment be fin-shaped.

The act of depositing dielectric material in the at least one cavity may be performed by the first CVD method.

By depositing dielectric material in the at least one cavity by the first CVD method, deposition of dielectric material elsewhere may be reduced or avoided altogether. Thus, cleaning steps may be reduced during production.

By depositing dielectric material in the at least one cavity by the first CVD method, a MDI with little or no curving profile may be provided. Thus, the ends of the MDI may be flat.

Both acts of depositing dielectric material in the at least one cavity, and depositing dielectric material in the recesses of the first sacrificial layers, may be performed by the first chemical vapor deposition method.

Thus, cleaning steps may be further reduced during production. A MDI and inner spacers with little or no curving profile may be provided (e.g., achieved). Thus, the ends of both of the MDI and the inner spacers may be flat.

Depositing dielectric material in the at least one cavity, and depositing dielectric material in the recesses of the first sacrificial layers, may be performed simultaneously.

Depositing dielectric material in the at least one cavity and in the recesses (e.g., simultaneously) may simplify the manufacturing process.

The act of depositing dielectric material in the at least one cavity and in the recesses (e.g., simultaneously) implies that the dielectric material in the at least one cavity and the recesses may be of the same material.

A material of the channel layers may be Si₁₋ₐGeₐ, a material of the liner layers may be Si_{1-b}Ge_{b}, the first sacrificial semiconductor material may be Si_{1-c}Ge_{c}, and the second sacrificial semiconductor material may be Si_{1-d}Ge_{d}, wherein 0≤a≤b<c<d.

The channel layer may be formed of a channel material being Si₁₋ₐGeₐ. The channel material may be Si. As such, “a” may be equal to 0.

The liner layer may be formed of a liner layer material being Si_{1-b}Ge_{b}. The layer material may be Si. As such, “b” may be equal to 0.

The first sacrificial layer may be formed of a first sacrificial material being Si_{1-c}Ge_{c}.

The second sacrificial layer may be formed of a second sacrificial material being Si_{1-d}Ge_{d}.

The first and second sacrificial materials may be chosen such that “d” is greater than “c.” In other words, the Ge-content of the second sacrificial material may be greater than that of the first sacrificial material. The first sacrificial layer may thus be formed of a first sacrificial material having low Ge-content. In other words, layers adjacent to the channel layers may have low Ge-content. The second sacrificial layer may thus be formed of a second material having high Ge-content. The second sub-stack may hence comprise a plurality of sacrificial layers alternating between having high and low Ge-content.

The first sacrificial semiconductor material may have such a composition that “c” is in a range of 0.1-0.25. The second sacrificial semiconductor material may have such a composition that “d” is in a range of 0.35-0.5.

In an example embodiment, the first sacrificial material may be Si_{0.75}Ge_{0.25}, and the second sacrificial material may be Si_{0.5}Ge_{0.5}. Such relative differences in Ge-content may facilitate a selective processing (e.g., selective etching) of the different sacrificial layers, the liner layers, and the channel layers of the layer stack.

A material of the liner layers may have such a composition that “b” is below 0.05.

By way of example, the liner layer material may be Si_{0.98}Ge_{0.02}. Thus, the Ge-content of the liner layers may be (e.g., sufficiently) different from the Ge-contents of the sacrificial layers. Such relative differences in Ge-content may facilitate a selective processing (e.g., selective etching) of the different sacrificial layers and the channel layers of the layer stack, while providing (e.g., enabling) little or no erosion of the liner layers.

The dielectric material deposited by the first CVD method may comprise SiOC or SiOCN.

Such materials may provide (e.g., sufficient) electrical isolation between the channel(s) of the first sub-stack and channel(s) of the third sub-stack.

The act of forming recesses in the first sacrificial layers of the layer stack may be performed before the act of removing the at least one second sacrificial layer of the second sub-stack, and may be performed using a first selective etch being selective to material of the channel layers and material of the liner layers but not to the first and second sacrificial semiconductor material.

Thus, the channel layers and the liner layers may remain in the layer stack while the first and second sacrificial layers may be etched. The channel layers and the liner layers may be subjected to little or no erosion.

The act of removing the at least one second sacrificial layer of the second sub-stack may be performed using a second selective etch being selective to material of the channel layers, material of the liner layers, and the first sacrificial semiconductor material but not to the second sacrificial semiconductor material.

Thus, the channel layers, the liner layers, and the first sacrificial layers may remain in the layer stack while the second sacrificial layers may be etched. The channel layers, the liner layers, and the first sacrificial layers may be subjected to little or no erosion.

A thickness of the liner layers may be in a range of 1 nm to 5 nm.

In an example embodiment, a thickness of the liner layers may be 1 nm, 2 nm, 3 nm, 4 nm, or 5 nm. In another example embodiment, a thickness of the liner layers may be below 2 nm, 3 nm, 4 nm, or below 5 nm. Such a thickness of the liner layers provides (e.g., sufficient) protection for the first sacrificial layers of the second sub-stack when removing the second sacrificial layers, while (e.g., simultaneously) providing a semiconductor structure being thin. This provides (e.g., enables) further device scaling. Also, a reduced growth thickness of the liner layers may provide (e.g., enable) a reduced amount of growth defects of the layer stack. The liner layers may be thin enough to prevent parasitic source and drain epitaxial growth.

Further, such a liner thickness may prevent diffusion of atoms throughout the layer stack during processing steps such as annealing, while still providing (e.g., enabling) a comparably thin semiconductor structure.

The recesses may comprise isotropic selective etching of the end surfaces of the first sacrificial layers from opposite ends of the layer stack.

Due to the liner layers, rounding of corners of the first sacrificial layers may be avoided, even if the etching of end surfaces of the first sacrificial layers is done isotropically. In other words, the use (e.g., employment) of liner layers provides (e.g., enables) isotropic selective etching while avoiding rounding of corners of the first sacrificial layers. Isotropic etching of the end surfaces provides (e.g., allows) for a controlled formation of the recesses. As such, this facilitates subsequent processing steps, e.g., the act of depositing dielectric material in the cavities/recesses.

The method may further comprise forming a sacrificial gate structure extending across the layer stack. The sacrificial gate structure may comprise a sacrificial gate body and a first spacer on opposite sides of the sacrificial gate body, wherein the source/drain recesses are formed by etching through the device layer stack while using the sacrificial gate structure as an etch mask such that portions of the first, second, and third sub-stacks of the layer stack are preserved underneath the sacrificial gate structure.

The method may accordingly provide an (e.g., efficient) manufacturing of the semiconductor structure.

The method may further comprise forming source and drain regions by epitaxially growing semiconductor material on channel layer end surfaces exposed in the source/drain recesses.

### BRIEF DESCRIPTION OF THE FIGURES

The above, as well as additional objects, features of the present concept, will be better understood through the following illustrative and non-limiting detailed description, with reference to the appended drawings. In the drawings like reference numerals will be used for like elements unless stated otherwise.

FIGS. 1AA, 1BB, 1A, 1B, 1C, 2A, 2B, 3A, 3B, 4A, 4B, 5A, 5B, 6A, 6B, 7A, 7B, 8A, 8B, 9A, 9B, 10A, 10B, 11A, 11B, 12A, and 12B the semiconductor structure formation steps of a method applied to a semiconductor device in a schematically depicted cross-sectional view, according to example embodiments.

FIGS. 13AA, 13AAA, 13AAAA, 13A, 13B, 13C, 14A, 14B, 15A, 15B, 16A, and 16B illustrate the semiconductor structure formation steps of a method applied to a semiconductor device in a schematically depicted cross-sectional view, according to example embodiments.

The figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

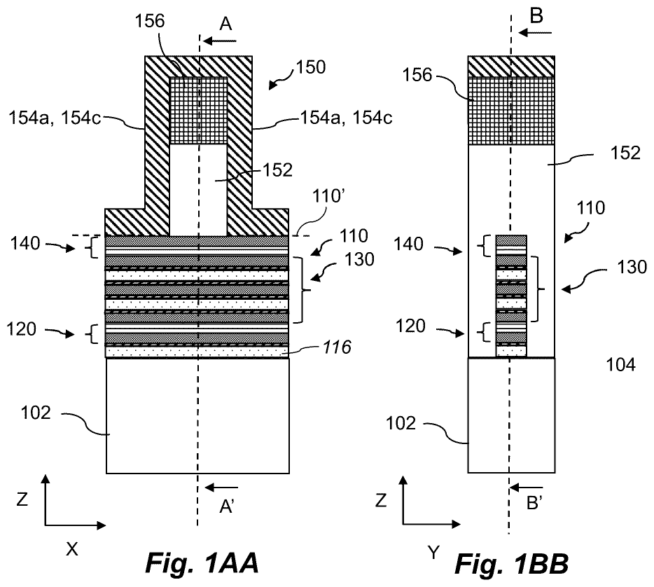

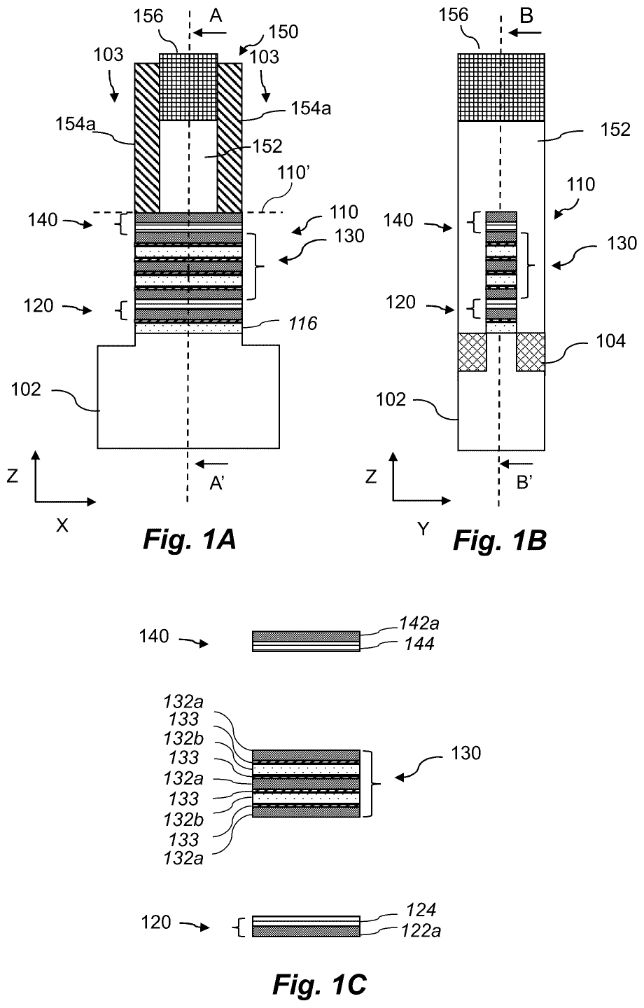

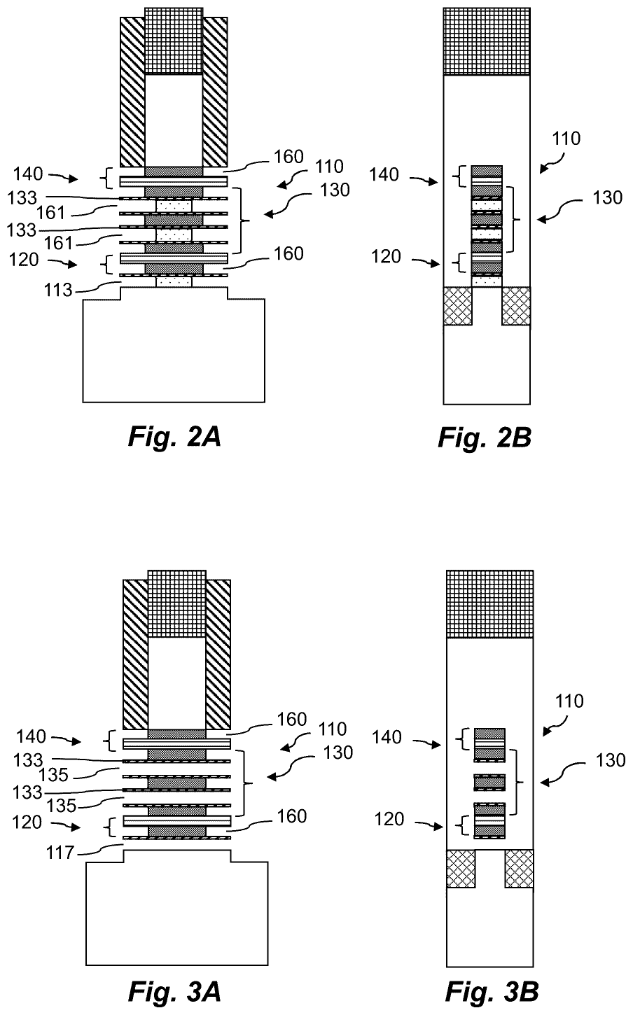

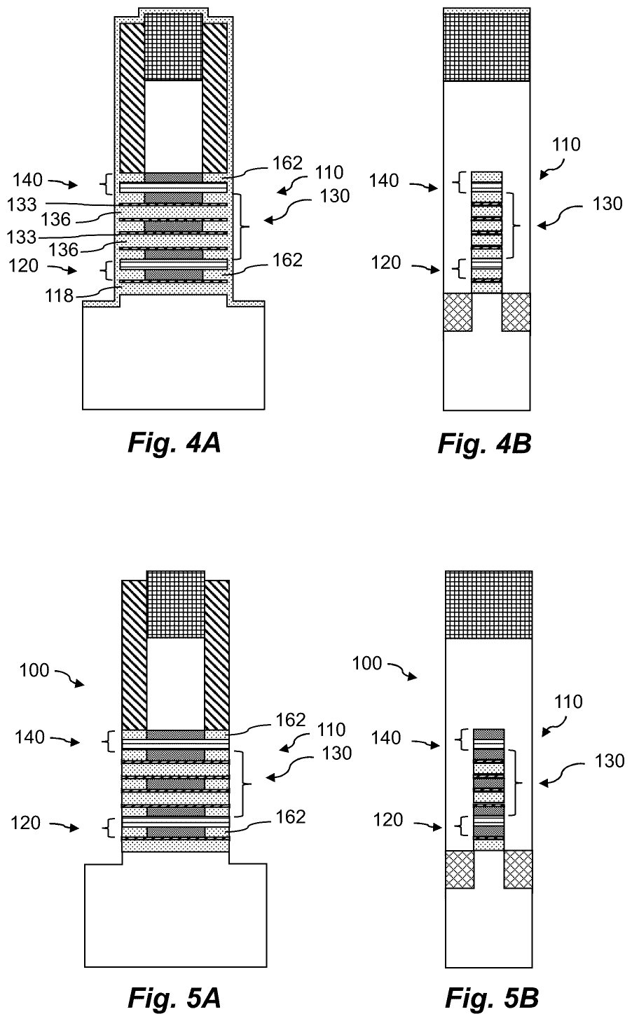

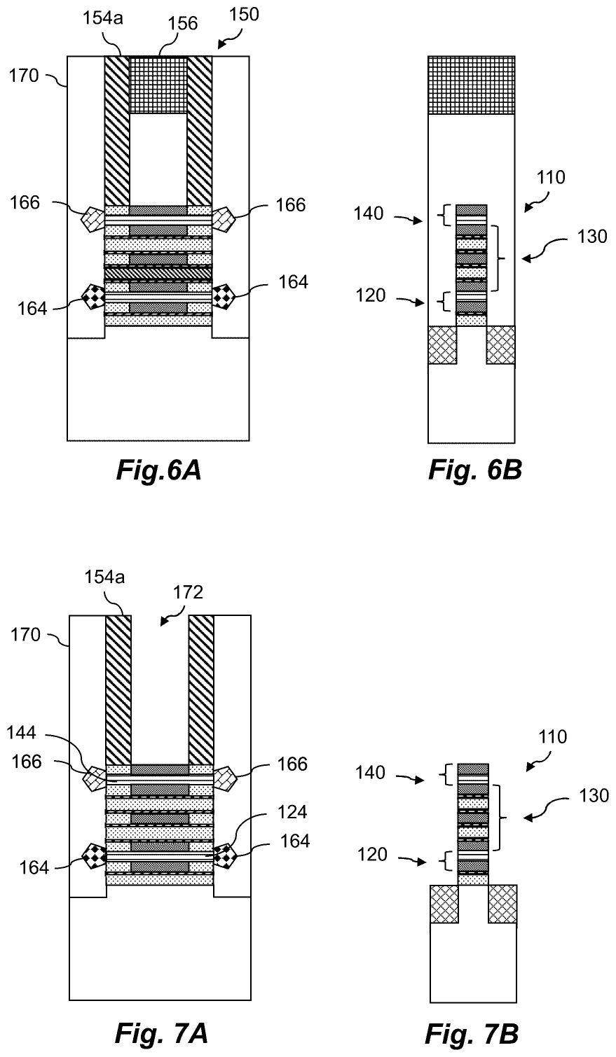

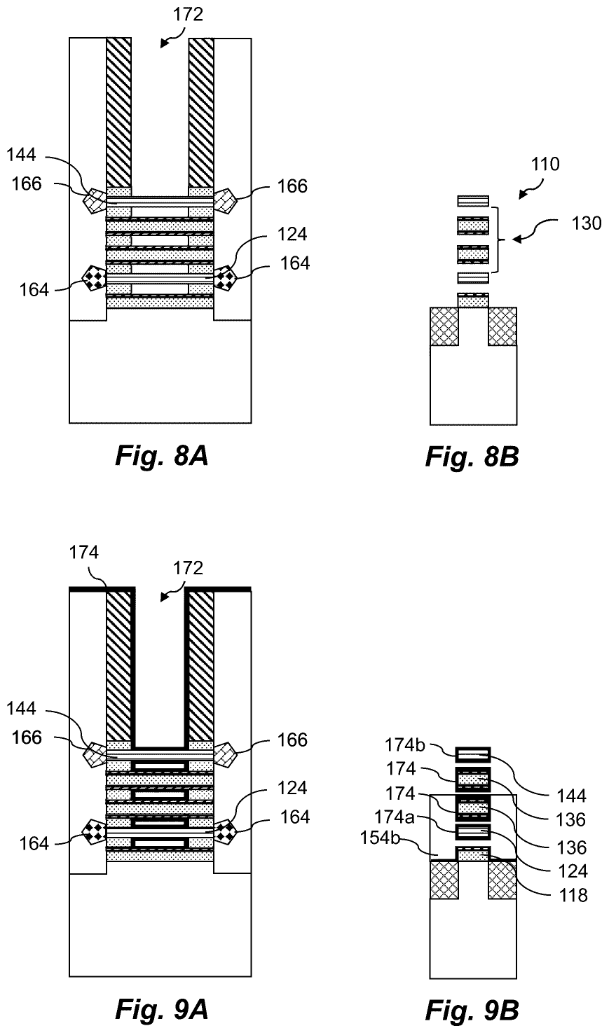

FIGS. 1AA, 1BB, 1A, 1B, 1C, 2A, 2B, 3A, 3B, 4A, 4B, 5A, and 5B illustrate one example embodiment of the method according to the disclosure. This may be called embodiment A. FIGS. 1AA and 1BB depict a layer stack 110 at an initial stage of a method for forming a resulting semiconductor structure 100. FIGS. 1AA, 1BB, 1A, 1B, 1C, 2A, 2B, 3A, 3B, 4A, 4B, 5A, 5B illustrate the formation of a semiconductor structure 100, wherein the finished semiconductor structure 100 is shown in FIGS. 5A, 5B, FIGS. 6A, 6B, 7A, 7B, 8A, 8B, 9A, 9B, 10A, 10B, 11A, 11B, 12A, and 12B then shows the formation of a device structure (e.g, stack of FETs) 1000 starting from the semiconductor structure 100. The stack of FETs 1000 may be a CFET device.

Axes X, Y and Z indicate a first direction, a second direction transverse to the first direction, and a vertical or bottom-up direction, respectively. The X-direction and Y-direction may in an example embodiment be referred to as lateral or horizontal directions in that they are parallel to a main plane of a substrate 102 of the structure 100. The Z-direction is parallel to a normal direction to the substrate 102.

FIGS. 1AA and 1BB depict respective cross-sectional views of the layer stack 110 taken along vertical planes B-B′ (e.g., parallel to the XZ-plane) and A-A′ (e.g., parallel to the YZ plane). The cross-sectional views of the figures correspond to those in FIGS. 1AA-1BB unless stated otherwise.

The layer stack 110 is arranged on a substrate 102. The substrate 102 may be a suitable (e.g., conventional) semiconductor substrate suitable for complementary FETs. The substrate 102 may be a single-layered semiconductor substrate, for example, formed by a bulk substrate such as a Si substrate, a germanium (Ge) substrate or a silicon-germanium (SiGe) substrate. A multi-layered/composite substrate is however also possible, such as an epitaxially grown semiconductor layer on a bulk substrate, or a semiconductor-on-insulator (SOI) substrate, such as a Si-on-insulator substrate, a Ge-on-insulator substrate, or a SiGe-on-insulator substrate.

The device layer stack 110 comprises a first sub-stack 120, a second sub-stack 130 on the first sub-stack 120, and a third sub-stack 140 on the second sub-stack 130.

FIG. 1C depicts the first sub-stack 120 (bottom), the second sub-stack 130 (middle), and the third sub-stack 140 (top) in isolation (e.g., for illustrational clarity).

The first sub-stack 120 comprises a first sacrificial 122a and a channel layer 124 on the first sacrificial layer 122a. The channel layer 124 forms a top (e.g., topmost) layer of the first sub-stack 120. The layers 122a and 124 may be referred to as one unit of the first sub-stack 120. Although FIG. 1C depicts (e.g., merely) one such unit (e.g., a single) of the first sub-stack 120, the first sub-stack 120 may comprise more than (e.g., merely) a single unit. In an example embodiment, the first sub-stack 120 may e.g., comprise two, three, four, or more units. As such, the first sub-stack 120 may comprise two, three, four, or more first sacrificial layers 122a and channel layers 124, respectively. In case the first sub-stack 120 comprises a plurality of such units, the units may be consecutively arranged. In an example embodiment, the units may be arranged on top of each other.

The second sub-stack 130 comprises a plurality of sacrificial layers alternating between first and second sacrificial layers 132a, 132b. Neighboring first and second sacrificial layers 132a, 132b of the second sub-stack 130 are separated by a liner layer 133. It may thus be that the liner layer 133 may abut each first and second sacrificial layer 132a, 132b that it separates.

FIG. 1C illustrates a second sub-stack 130 comprising (e.g., along a bottom-up direction) a bottommost first sacrificial layer 132a, a liner layer 133, a second sacrificial layer 132b, a liner layer 133, a first sacrificial layer 132a, a liner layer 133, a second sacrificial layer 132b, a liner layer 133, and a topmost first sacrificial layer 132a. The bottommost first sacrificial layer 132 is thus arranged on the first sub-stack 120, e.g., on the topmost channel layer 124. Although FIG. 1C depicts merely two second sacrificial layers 132b of the second sub-stack 130, the second sub-stack 130 may comprise more than (e.g., merely) two second sacrificial layers 132b. The second sub-stack 130 may comprise one (e.g., a single) second sacrificial layer 132b.

The third sub-stack 140 comprises a channel layer 144 and a first sacrificial layer 142a on the channel layer 144. The channel layer 144 forms a bottom (e.g., bottom-most) layer of the third sub-stack 140. The channel layer 144 is thus arranged on the second sub-stack 130, e.g., on the topmost first sacrificial layer 132a. The layers 144 and 142a may be referred to as one unit of the third sub-stack 140. Although FIG. 1C depicts (e.g., merely) one such unit (e.g., a single) of the third sub-stack 140, the third sub-stack 140 may comprise more than (e.g., merely) a single unit. In an example embodiment, the third sub-stack 140 may e.g., comprise two, three, four, or more units. As such, the third sub-stack 140 may comprise two, three, four, or more first sacrificial layers 142a and channel layers 144, respectively. In case the third sub-stack 140 comprises a plurality of such units, the units may be consecutively arranged. In an example embodiment, the units may be arranged on top of each other.

The first sacrificial layers 122a, 132a, 142a of the first through third sub-stacks 120, 130, 140 and the second sacrificial layers of the first through third sub-stacks 120, 130, 140 may be formed with a uniform or at least similar thickness. The second sacrificial layers may be formed with a greater thickness than each of the first sacrificial layers 122a, 132a, 142a of the first through third sub-stacks 120, 130, 140. The total thickness of the second sub-stack 130 may (e.g., accordingly) exceed a thickness of each first sacrificial layer of the first sub-stack 120 and the third sub-stack 140.

The channel layers of the first and third sub-stacks 120, 140 may also be of a uniform or at least similar thickness, e.g., a different or a same thickness as the first sacrificial layers of the layer stack 110.

Each of the liner layers of the second sub-stack 130 may be of a uniform or at least similar thickness.

In an example embodiment, the channel layers of the first and third sub-stacks 120, 140 may each be formed with a thickness of 3-10 nm, the first sacrificial layers 122a, 132a, 142a of the first through third sub-stacks 120, 130, 140 may each be formed with a thickness of 3-10 nm, the second sacrificial layers 132b may be formed with a thickness of 5-30 nm, and the liner layers 133 may be formed with a thickness of 1-5 nm. In an example embodiment, the liner layers 133 are 2-3 nm. The total thickness of the second sub-stack 130 may, for example, be 20-50 nm.

Each first sacrificial layer 122a, 132a, 142a of the first through third sub-stacks 120, 130, 140 is formed of a same first sacrificial material.

The second sacrificial layer(s) 132b of the second sub-stack 130 is formed of a second sacrificial material different from the first sacrificial material. Each channel layer 124, 144 of the first and third sub-stacks 120, 140 is formed of a same channel material, different from each of the first and second sacrificial materials. The liner layers 133 are formed of a semiconductor material different from the first and second semiconductor materials.

For example, the channel material may be Si₁₋ₐGeₐ, the liner material may be Si_{1-b}Ge_{b}, the first sacrificial material may be Si_{1-c}Ge_{c}, and the second sacrificial material may be Si_{1-d}Ge_{d}, wherein 0≤a≤b<c<d. For example, “c” may be in a range of 0.1-0.25. Further, “d” may be in a range of 0.35-0.5. In an example embodiment, the channel material may be Si (e.g., a=0), the liner material may be Si (e.g., “b”=0), the first sacrificial material may be Si_{0.75}Ge_{0.25}, and the second sacrificial material may be Si_{0.5}Ge_{0.5}. The relative differences in Ge-content facilitate a selective processing (e.g., selective etching) of the different sacrificial layers, the liner layers 133, and the channel layers of the layer stack 110.

The layers of the device layer stack 110 may each be epitaxial layers, e.g., epitaxially grown using deposition techniques, such as chemical vapor deposition (CVD) or physical vapor deposition (PVD). This provides (e.g., enables) (e.g., high quality) material layers with a useful degree of control of composition and dimensions.

The deposited layers may be (e.g., sequentially) formed and (e.g., subsequently) patterned to provide (e.g., define) an elongated fin-shaped layer stack, extending in the X-direction. The dashed line 110′ schematically indicates a contour of the layer stack 110 subsequent to fin patterning and prior to fin recess, described herein. While the figures depict only a single layer stack, a plurality of parallel fin-shaped layer stacks may be formed. Suitable (e.g., conventional) fin patterning techniques may be used, e.g., single patterning techniques such as lithography and etching (“litho-etch”) or multiple-patterning techniques such as (litho-etch) x, self-aligned double or quadruple patterning (SADP or SAQP).

The layers of the layer stack 110 may each be formed as nanosheets, e.g., with a width (along Y) to thickness (along Z) ratio greater than 1, such as a width in a range from 10 nm to 30 nm and a thickness in a range from 3 nm to 10 nm. In an example embodiment, patterning the layer stacks may be that the channel layers form nanowire-shaped layers. A nanowire may in an example embodiment may have a thickness similar to the (e.g., example) nanosheet however with a smaller width, such as 3 nm to 10 nm.

As shown in FIGS. 1A and 1B, subsequent to the fin patterning, a lower portion of the device layer stack 110 may be surrounded by a shallow trench isolation (STI) 104, e.g., of SiO₂.

As further shown in FIGS. 1AA and 1BB, a sacrificial gate structure 150 may be formed to extend across the layer stack 110. The sacrificial gate structure 150 comprises a sacrificial gate body 152 (e.g., and a gate spacer 154a, discussed herein). The sacrificial gate body 152 may be formed by depositing a sacrificial gate body material (e.g., amorphous Si) over the layer stack 110 and (e.g., subsequently) patterning the sacrificial gate body 152 therein. While the figures depict (e.g., only) a sacrificial gate structure 150, a plurality of parallel sacrificial gate structures may be formed across the layer stack 110. Suitable (e.g., conventional) patterning techniques may be used, e.g., single patterning techniques such as lithography and etching (“litho-etch”) or multiple-patterning techniques such as (litho-etch) x, SADP or SAQP.

The sacrificial gate structure 150 is further conformally coated by a gate spacer material 154c. The gate spacer material 154c may be dielectric material, e.g., as an oxide, a nitride or a carbide such as SiN, SiC, SiCO, SiCN, SiOCN, SiON, or SiBCN deposited by ALD.

The sacrificial gate structure 150 may, as shown, further comprise a capping layer 156, e.g., formed of one or more layers of hardmask material remaining from the sacrificial gate body patterning.

FIGS. 1A and 1B illustrate the formation of source/drain recesses 103.

After forming the sacrificial gate structure 150 the device layer stack 110 may be recessed by etching back the device layer stack 110 in a top down direction (e.g., negative Z) while using the sacrificial gate structure 150 as an etch mask. The etching may extend through each of the third, second, and first sub-stacks 140, 130, 120 such that portions of each layer thereof are preserved underneath the sacrificial gate structure 150, as shown in FIG. 1A. In FIGS. 1A and 1B, etching back the device layer stack 110 has formed recesses 103 in the layer stack 110. A respective recess 103 may be formed in the layer stack 110 at opposite sides of the layer stack 110. The recesses 103 may extend into the substrate.

After forming the source/drain recesses 103, portions of the gate spacer material 154c that remain on the end surfaces of the sacrificial gate body 152 provide (e.g., define) a first spacer or first spacer layer 154a on opposite sides of the sacrificial gate body 152. The first spacer 154a may also be referred to as gate spacer 154a.

Each of the first sacrificial layers 122a, 132a, 142a of the first through third sub-stacks 120, 130, 140 may be subjected to the same process steps. Hence, for brevity, these layers may in the following be (e.g., commonly) denoted as the first sacrificial layers of the device layer stack 110, or of the first sub-stack 120, the second sub-stack 130 or the third sub-stack 140. For corresponding reasons, the channel layers of the first and third sub-stacks 120, 140 (124, 144) may in the following be (e.g., commonly) denoted the channel layers of the layer stack 110, or of the first sub-stack 120 or the third sub-stack 140.

FIGS. 2A and 2B show the formation of recesses 160 in the first sacrificial layers of the layer stack. The formation of recesses 160 may be formed subsequently to forming source/drain recesses 103.

In FIG. 2A, recesses 160 have been formed in the layer stack 110 by laterally etching back (e.g., along the X- and negative X-direction) end surfaces of each first sacrificial layer of the layer stack 110 from opposite ends of the layer stack 110, by selective etching. The lateral etch back may be provided by an isotropic etching process. Any suitable dry etching process or wet etching process providing (e.g., allowing) selective etching of the first sacrificial material may be used (e.g., HCl, or APM). As indicated in FIG. 2A, the extent of the lateral etch back may correspond to a thickness of the gate spacer 154a. In other words, a depth of the recesses 160 (e.g., along the X-direction) may correspond to the thickness of the gate spacer 154a (along the X-direction).

The act of forming the recesses 160 in the first sacrificial layers 122a, 132a, 142a may also be accompanied by the act of forming recesses 161 in the second sacrificial layers 132b. The formation of recesses 160 in the first sacrificial layers 122a, 132a, 142a may be performed simultaneous with the act of forming recesses 161 in the second sacrificial layers 132b. Alternatively, recesses 161 may be formed in the second sacrificial layers 132b first. Recesses 160 may (e.g., subsequently) be formed in the first sacrificial layers.

As indicated in FIG. 2A, the extent of the lateral etch back of the second sacrificial layers 132b may correspond to a thickness greater than that of the gate spacer 154a. In other words, a depth of the recesses 161 (e.g., along the X-direction) may be greater than the thickness of the gate spacer 154a and the recess 160 (along the X-direction). The first and second sacrificial layers may have different Ge-content and may thus be removed at a different rate depending on the etchant used. An etchant having a higher etch rate for material having a comparably high Ge-content may be used. Hence, (e.g., it may be implied that) the material of the second sacrificial layers 132b have a higher Ge-content.

As further seen in FIG. 2A, the liner layers 133 may prevent rounding of the corners of the first sacrificial layers 132a of the second sub-stack 130. Even if the second sacrificial layers 132b of the second sub-stack 130 may etch faster than the first sacrificial layers 132a of the second sub-stack 130, the etchant may not attack the first sacrificial layers 132a via the recesses 161 in the second sacrificial layers 132b due to the protective liner layers 133. Thus, the first sacrificial layers 132a of the second sub-stack 130 may (e.g., only) be attacked laterally via the recesses 160 of the second sub-stack 130.

FIGS. 3A and 3B show the removal of the second sacrificial layers of the second sub-stack.

In FIG. 3A, the second sacrificial layers 132b of the second sub-stack 130 have been removed by selectively etching the second sacrificial semiconductor material, thereby forming a cavity 135 in the second sub-stack 130. The removal of the second sacrificial layers may occur prior to the deposition of dielectric material into any cavities or recesses. The second sacrificial semiconductor material may be etched using an isotropic etching process (wet or dry), to laterally etch back end surfaces of the second sacrificial layers 132b from opposite sides of the layer stack 110. For example, an HCl-based dry etch may be used to remove second sacrificial layer material having smaller Ge-content than that of the first sacrificial material. However, other appropriate etching processes (e.g., wet etching processes) may also be employed for this purpose.

FIGS. 4A and 4B show deposition of dielectric material in both the cavities 135 and the recesses 160.

In FIGS. 4A and 4B, the cavities 135 and the recesses 160 have been filled with a dielectric material, e.g., such as SiOC or SiOCN. As such, the dielectric material in the cavities 135 and the recesses 160 may be the same. The dielectric material is herein deposited by UCVD, (e.g., simultaneously) in both the cavities 135 and the recesses 160. In an example embodiment, a dielectric material include SiOC or SiOCN.

As seen in FIG. 4A, the dielectric material deposited by UCVD may (e.g., preferentially) fill the cavities 135 and the recesses 160 and leave only a thin film of dielectric material, or no film, on the end surfaces of the layer stack. Thus, the end surfaces of the layer stack may, after deposition of the dielectric material be flat. If another deposition method had been used, the end surfaces of the layer stack may have been less flat. If another deposition method had been used, a surface of the dielectric material may be non-flat with protrusions over end surfaces of channel layers and liner layers, and/or indentations in the regions of the filled cavities 135 and recesses 160.

The first CVD method may comprise reacting, as a film-forming gas, an oxygen-containing silicon compound gas with a non-oxidizing hydrogen-containing gas in a state in which at least the non-oxidizing hydrogen-containing gas is plasmarized, to form a film of a flowable silanol compound, and, subsequently, annealing the film of flowable silanol compound into the first dielectric material, wherein the oxygen-containing silicon compound gas comprises Si_{α}O_{β}(O—CₘHₙ)_{Γ}CₓH_{y}, wherein m, n, and α are integers of 1 or more, and wherein β, Γ, x, and y are integers of 0 or more, and β and Γ are not 0 at the same time.

The first CVD method may be called Ultra Chemical Vapor Deposition (UCVD) or Chemical Vapor Liquid Deposition. In the following description the term UCVD may (e.g., primarily) be used. The UCVD method may be useful over ALD, and other (e.g., conventional) methods, when filling the cavities 135 and recesses 160 with dielectric material. The usefulness of the UCVD method compared to other (e.g., conventional) methods such as ALD is discussed herein and may for brevity not be elaborated any further.

The dielectric material has been subjected to an isotropic etching process to remove portions of the dielectric material deposited outside the respective cavity 135. Any suitable isotropic etching process (e.g., wet or dry) for etching the dielectric material (e.g., SiOC or SiOCN) may be used. The dielectric material remaining in the respective recess 160 forms the respective dielectric layer inner spacer 162. The dielectric material remaining in the respective cavity 135 forms the respective dielectric layer 136.

As discussed herein, although FIG. 1C depicts two second sacrificial layers 132b of the second sub-stack 130, the second sub-stack 130 may comprise more than (e.g., merely) two second sacrificial layers 132b. The second sub-stack 130 may comprise one (e.g., a single) second sacrificial layer 132b. Thus, subsequent processing steps may involve forming at least one dielectric layer 136.

FIGS. 4A and 4B show end surfaces of channel layers being exposed.

As further shown in FIG. 5A, the inner spacers 162 and the dielectric layers 136 have been formed in the recesses 160 and the cavities 135, respectively, by subjecting the dielectric material to an isotropic etching process to remove portions of the dielectric material deposited outside the recesses 160 and the cavities 135. Any suitable isotropic etching process (e.g., wet or dry) for etching the dielectric material (e.g., SiOC or SiOCN) may be used. The etching may as shown be stopped when end surfaces of the channel layers of the layer stack 110 are exposed and discrete portions of the dielectric material remain in the recesses 160 and the cavities 135 to form the inner spacers 162 and the dielectric layers 136, respectively.

As shown in FIG. 1A, the layer stack 110 may also comprise a bottom second sacrificial layer 116. The bottom second sacrificial layer 116 may be arranged between the substrate 102 and the first sub-stack 120. A liner layer 133 may also be arranged between the bottom second sacrificial layer 116 and the first sub-stack 120. The liner layer 133 may separate the bottom second sacrificial layer 116 from the first sub-stack 120. The liner layer 133 may abut the bottom second sacrificial layer 116 and the first sacrificial layer 122a of the first sub-stack 120.

The bottom second sacrificial layer 116 may be subject to the (e.g., same) processing steps as the second sacrificial layers 132b of the second sub-stack 130 (e.g., and the first sacrificial layers of the sub-stacks 120, 130, 140). Hence, for brevity, the processing steps may not be elaborated in detail.

In FIGS. 2A, 2B, 3A, and 3B, the bottom second sacrificial layer 116 arranged between the substrate 102 and the bottom channel layer 112 has been removed by etching, thereby forming recesses 113 and (e.g., subsequently) a bottom cavity 117.

In FIG. 4A, the bottom cavity 117 has been filled with a dielectric material. The dielectric material may be the same dielectric material that has filled the recesses 160 and the cavities 135.

The dielectric material has been subjected to an isotropic etching process to remove portions of the dielectric material deposited outside the bottom cavity 117. Any suitable isotropic etching process (e.g., wet or dry) for etching the dielectric material (e.g., SiN) may be used. The dielectric material remaining in the bottom cavity 117 forms the dielectric layer 118.

In FIGS. 6A and 6B, source and drain regions 164 and 166 have been formed on the channel layer(s) of the first sub-stack 120 and the third sub-stack 140, respectively. The source and drain regions 164, 166 have been formed by epitaxially growing semiconductor material on end surfaces of the channel layers exposed at opposite sides of the sacrificial gate structure 150. The source and drain regions 164, 166 may be formed by epitaxially growing semiconductor material on channel layer end surfaces exposed in the source/drain recesses 103.

The source and drain regions 164 formed on the channel layer end surfaces of the first sub-stack 120 may be of a first conductivity type and the source and drain regions 166 formed on the channel layer end surfaces of the third sub-stack 140 may be of a second opposite conductive type. The first and second conductivity types may be a p-type and an n-type, or vice versa. The doping may be provided (e.g., achieved) by in-situ doping. Different conductivity types of the source and drain regions 164 and the source and drain regions 166 may be provided (e.g., achieved) by masking the channel layer end surfaces of the third sub-stack 140 while performing epitaxy on the channel layer end surfaces of the first sub-stack 120. The masking of the channel layer end surfaces of the third sub-stack 140 may for example be provided by forming a temporary cover spacer along the third sub-stack 140. After completing the epitaxy of the source and drain regions 164, the temporary cover spacer may be removed and the source and drain regions 164 may be covered with one or more dielectric materials (e.g., ALD-deposited SiN and an inter-layer dielectric like SiO₂). Epitaxy may then be performed on the channel layer end surfaces of the third sub-stack 140. This is however (e.g., merely) an (e.g., one) example and other process techniques facilitating forming of the source and drain regions 164, 166 with different conductivity types may also be used.

The source and drain regions 164, 166 may as shown (e.g., subsequently) be embedded in, or encapsulated by an insulating layer 170. The insulating layer 170 may be formed of an insulating material, such as an oxide, e.g., SiO₂, or another inter-layer dielectric, deposited, planarized and recessed, e.g., by chemical mechanical polishing (CMP) and/or etch back. The CMP and/or etch back may proceed to also remove any capping layer 156 of the sacrificial gate structure 150. It is however also possible to stop the CMP and/or etch back on the capping layer 156 and (e.g., subsequently) open the capping using a separate etch step.

In FIGS. 7A and 7B, a gate trench 172 has been formed by removing the sacrificial gate body 152 between the opposite gate spacers 154a. Any suitable (e.g., conventional) etching process (e.g., isotropic or anisotropic) (e.g., wet or dry) providing (e.g., allowing) selective removal of the sacrificial gate body 152 (e.g., of amorphous Si) may be used.

In FIGS. 8A and 8B, the first sacrificial layers of the device layer stack 110 have been removed by (e.g., selectively) etching the first sacrificial semiconductor material from the gate trench 172. A same type of etching process may be used for this step as during the forming of the recesses 160. By removing the first sacrificial layers, the channel layers of the device layer stack 110 may be released in the sense that upper and lower surfaces thereof may be exposed within the gate trench 172. Thus, second cavities 155 are formed. As the dielectric layer prior to this process step was surrounded by first dielectric layers (e.g., the first dielectric layer 132a and the second dielectric layer 132b of the second sub-stack 130), also the dielectric layer is released.

FIGS. 9A, 9B, 10A, 10B, 11A, 11B, 12A, and 12B illustrate process steps for forming a gate stack 180 surrounding the released channel layers and the dielectric layers 136 in the gate trench 172.

In FIGS. 9A and 9B, a gate dielectric layer and then a first gate work function metal (WFM) (e.g., layer) 174 have been conformally deposited in the gate trench 172. The gate dielectric layer is for illustrational clarity (e.g., not individually shown in the figures) but its coverage may correspond with that indicated for WFM 174. The gate dielectric layer may be formed of a (e.g., a conventional) high-k dielectric e.g., HfO₂, HfSiO, LaO, AlO or ZrO. The first WFM 174 may be formed of one or more effective WFMs (e.g., an n-type WFM such as TiAl or TiAlC and/or a p-type WFM such as TiN or TaN). The gate dielectric layer and the first WFM may be deposited by ALD.

As further shown in FIG. 9B, a block mask 154b may (e.g., subsequently) be formed in a lower part of the gate trench 172. The block mask 154b may be formed a thickness (e.g., along the Z-direction) such that the portions of the first WFM 174 surrounding the channel layers of the first sub-stack 120 (e.g., portion 174a surrounding the channel layer 124) is covered and the portions of the first WFM 174 surrounding the channel layers 144 of the third sub-stack 140 (e.g., the portion 174b surrounding the channel layer 144) are exposed.

The block mask 154b may be formed by depositing a block mask material filling the gate trench 172. The block mask material may e.g., be spin-on-carbon or another organic spin-on material. The block mask material may (e.g., subsequently) be etched back top-down (e.g., using an anisotropic etch) to a target level. The target level may as shown be located between the dielectric layers 136. The portions of the first WFM 174 surrounding the channel layers of the third sub-stack 140 may thus be exposed.

In FIGS. 10A and 10B, the first WFM 174 has been removed from the channel layer(s) of the third sub-stack 140 while using the block mask 154b as an etch mask. Depending on the provided (e.g., particular) thickness of the block mask 154b, at least a portion of the first WFM 174 surrounding the dielectric layers 136 may also be removed. The first WFM 174 surrounding the channel layer(s) to the first sub-stack 120 (e.g., the portion 174a surrounding the channel layer 124) may however be preserved, due to the block mask 154b.

The first WFM 174 may be removed using a suitable isotropic (wet or dry) etch, providing (e.g., allowing) selective removal of the first WFM 174 without removing the gate dielectric. Subsequently, the block mask 154b may be removed from the trench 172.

In FIGS. 11A and 11B, a second gate WFM 176 has been conformally deposited in the gate trench 172. The second WFM 176 may be deposited on the gate dielectric surrounding the channel layer(s) of the third sub-stack 140, and on portions of the gate dielectric exposed on the dielectric layers 136. The second WFM 176 may thus surround the channel layer(s) of the third sub-stack 140. As shown in FIGS. 11A and 11B, the second gate WFM 176 may further be deposited on the first WFM 174 surrounding the channel layer(s) of the first sub-stack 140.

The first WFM 174 may form a first gate stack. The second gate WFM 176 may for a second gate stack. Each of the first and second gate stacks may extend through the second cavities 155.

Subsequently, a gate fill metal 178 (such as W) may be deposited to fill a remaining space of the gate trench 172. The gate fill metal 178 may, in an example embodiment, be deposited by CVD or PVD.

The (e.g., full) gate stack 180, comprising a lower portion comprising the gate dielectric layer, the first WFM 174, the second WFM 176, and the gate fill metal 178 surrounding the channel layer(s) of the first sub-stack 110, and an upper portion comprising the gate dielectric, the second WFM 176 and the gate fill metal 178 surrounding the channel layer(s) of the third sub-stack 140.

FIGS. 12A and 12B depict the resulting device structure 1000 subsequent to a gate metal recess to bring a top surface of the gate stack 180 flush with an upper surface of the gate spacers 154a.

The device structure 1000 comprises a bottom device comprising the channel layer(s) of the first sub-stack 120, extending between the source and drain regions 164, and the lower portion of the gate stack 180. The device structure 1000 further comprises a bottom device comprising the channel layer(s) of the third sub-stack 140, extending between the source and drain regions 166, and the upper portion of the gate stack 180. The dielectric layers 136 remain as electrically inactive dummy channels, between the channel(s) of the bottom device and the top device and surrounded by the gate stack 180.

The method may (e.g., thereafter) proceed with forming source/drain contacts by etching contact trenches in the insulating layer 170 and depositing one or more contact metals in the trenches, on the source and drain regions 164, 166. Separate contacting of the source and drain regions of the bottom device and the top device may be provided (e.g., achieved) by a first contact metal deposition over the source and drain regions 164, 166, etch back of the contact metal to a level between the source and drain regions 164 and 166, thus exposing the source and drain regions 164, 166, deposition of an insulating contact separation layer on the etched back contact metal, and (e.g., subsequently) a second contact metal deposition over the source and drain regions 166. Separate source and drain contacting may be applied to either or both sides of the device structure 1000.

Alternative embodiments of the method are also possible. For example, cavities may be formed and dielectric material deposited in the cavities before the source/drain recessing.

For example, cavities may be formed and dielectric material deposited in the cavities before the source/drain recess, the dielectric material deposited in the cavities being deposited by a method other than the first CVD method. This may be referred to as embodiment B.

In another example embodiment, cavities may be formed and dielectric material deposited in the cavities before the source/drain recess, the dielectric material deposited in the cavities being deposited by the first CVD method. This may be referred to as embodiment C.

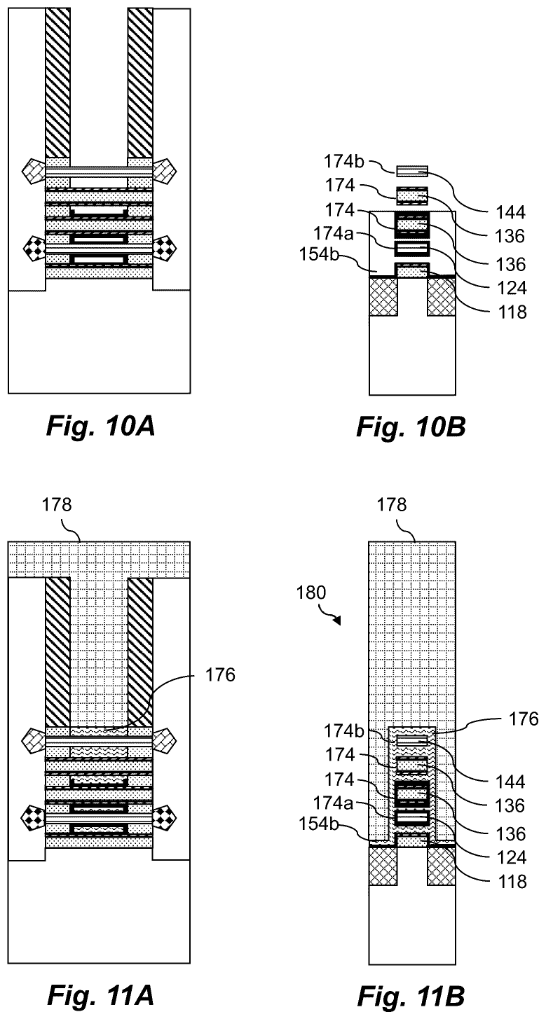

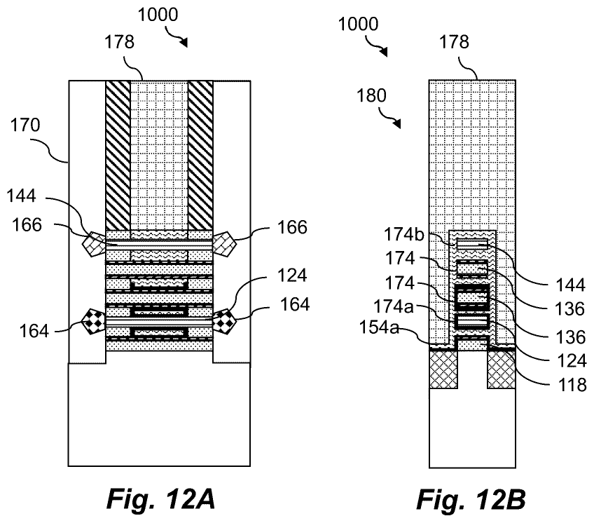

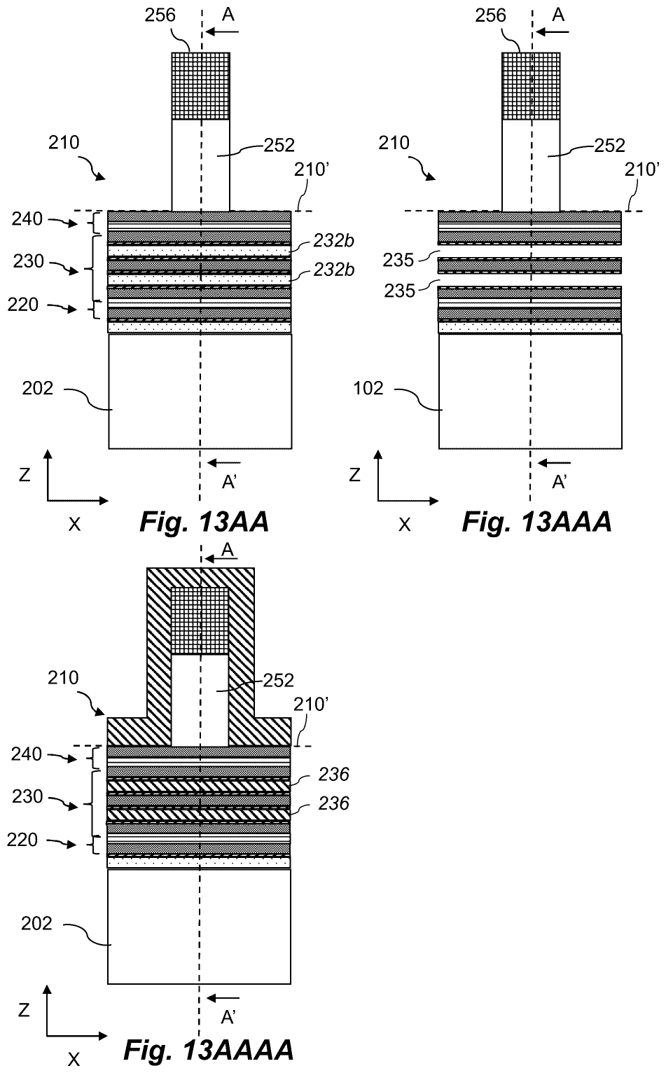

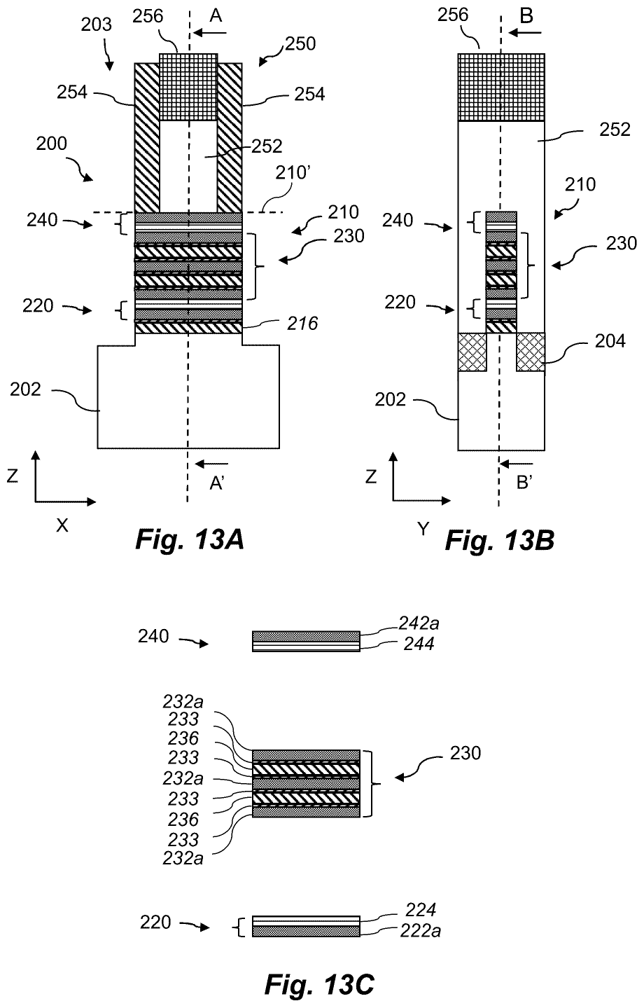

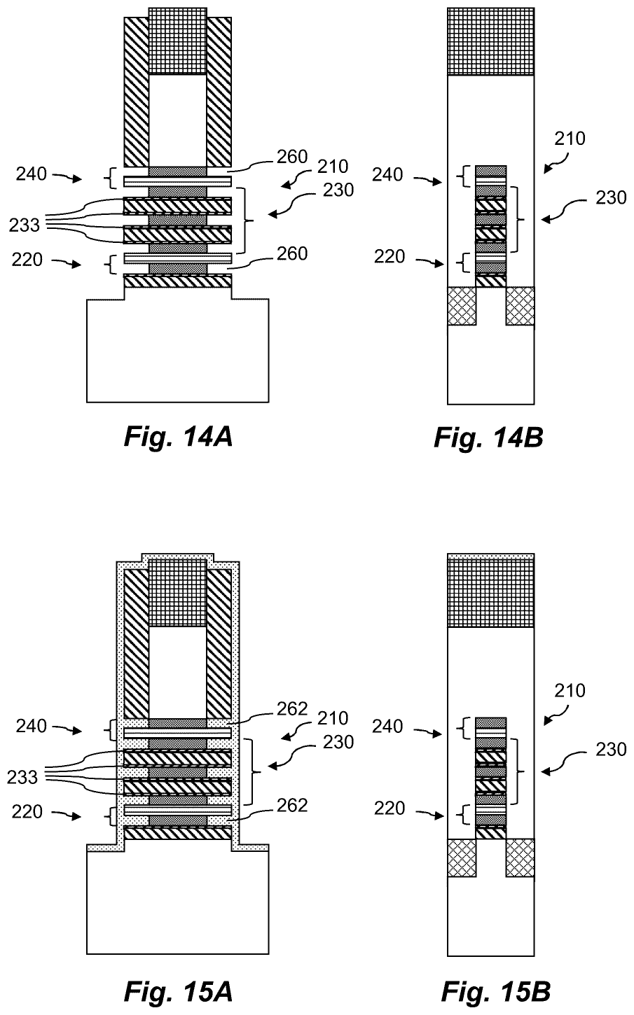

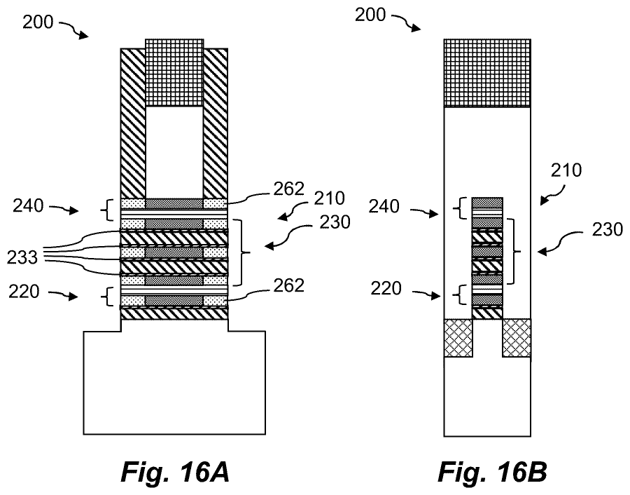

FIGS. 13AA, 13AAA, 13AAAA, 13A, 13B, 13C, 14A, 14B, 15A, 15B, 16A, and 16B illustrate embodiment B.

FIG. 13AA depict a layer stack 210 at an initial stage of a method for forming a resulting semiconductor structure 200. FIGS. 13AA, 13AAA, 13AAAA, 13A, 13B, 13C, 14A, 14B, 15A, 15B, 16A, and 16B illustrate the formation of a semiconductor structure 200, wherein the finished semiconductor structure 200 is shown in FIGS. 16A and 16B.

The layer stack 210 is similar to the layer stack 110 but illustrated before being coated by gate spacer material 254a. As illustrated in FIG. 13AAA, the second sacrificial layers 232b may then be removed to form cavities 235.

Dielectric material may (e.g., subsequently) be deposited in the cavities 235 to form dielectric layers 236. The dielectric layers 236 may be deposited by another method other than the first CVD method. For example, the dielectric layers 236 may be of the same material as the gate spacer material 254a and deposited (e.g., simultaneously) with the gate spacer material 254a, as indicated in FIG. 13AAAA. The dielectric layers 236 may be deposited by ALD, e.g., plasma enhanced ALD (PEALD). The dielectric layers 236 may comprise Si₃N₄.

As seen in FIG. 13C, the first sub-stack 220 comprises a first sacrificial 222a and a channel layer 224 on the first sacrificial layer 222a. The channel layer 224 forms a top (e.g., topmost) layer of the first sub-stack 220.

The second sub-stack 230 comprises (e.g., subsequent to fin recess) a plurality of sacrificial layers and dielectric layers alternating between first sacrificial layers 232a and dielectric layers 236. Neighboring first and second sacrificial layers 232a, 232b of the second sub-stack 230 are separated by a liner layer 233. The liner layer 233 may abut each first and second sacrificial layer 232a, 232b that it separates. The bottommost first sacrificial layer 232a is thus arranged on the first sub-stack 220, e.g., on the topmost channel layer 224.

The third sub-stack 240 comprises a channel layer 244 and a first sacrificial layer 242a on the channel layer 244. The channel layer 244 forms a bottom (e.g., bottom-most) layer of the third sub-stack 240. The channel layer 244 is thus arranged on the second sub-stack 230, e.g., on the topmost first sacrificial layer 232a.

FIGS. 13A and 13B illustrate the formation of source/drain recesses 203. This may be performed (e.g., analogously) with the description in conjunction with FIGS. 1A and 1B.

FIGS. 14A and 14B show the formation of recesses 260 in the first sacrificial layers of the layer stack 210. This may be performed (e.g., analogously) with the description in conjunction with FIGS. 2A and 2B, although the second sacrificial layers are not recessed, as the second sacrificial layers have (e.g., already) been replaced with dielectric material.

FIGS. 15A and 15B show deposition of dielectric material in the recesses 260 in the first sacrificial layers. This may be performed analogously with the description in conjunction with FIGS. 4A and 4B, e.g., using the first CVD method, although the dielectric material is not deposited in the cavities 235 since the cavities 235 are (e.g., already) filled.

FIGS. 16A and 16B show end surfaces of channel layers being exposed. This may be performed analogously with the description in conjunction with FIGS. 5A and 5B.

The rest of the processing for the source/drain (e.g., S/D), gate trench, and gate formation is analogous as described in conjunction with FIGS. 7A, 7B, 8A, 8B, 9A, 9B, 10A, 10B, 11A, 11B, 12A, and 12B.

With regards to an embodiment C, wherein cavities are formed and dielectric material is deposited in the cavities before the source/drain recess, the dielectric material deposited in the cavities may be deposited by the first CVD method. In this embodiment, both depositing dielectric material in the cavities and depositing dielectric material in the recesses of the first sacrificial layers, are performed by the first CVD method, albeit at different points in time. The dielectric material deposited in the recesses of the first sacrificial layers may be either the same as or different from the dielectric material deposited in the cavities.

This disclosure has (e.g., mainly) been described with reference to a limited number of examples. However, as is readily appreciated, examples, other than the examples disclosed herein, are (e.g., equally) possible within the scope of this disclosure and/or as provided by the appended claims.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method for forming a semiconductor structure, the method comprising:
forming a layer stack on a substrate, the layer stack comprising:
a first sub-stack comprising a first sacrificial layer and on the first sacrificial layer a channel layer providing a topmost layer of the first sub-stack,
a second sub-stack on the first sub-stack and comprising a plurality of sacrificial layers alternating between first and second sacrificial layers, wherein neighboring first and second sacrificial layers of the second sub-stack are separated by a liner layer, wherein first sacrificial layers provide a respective bottommost and topmost layer of the second sub-stack, the second sub-stack comprising at least one second sacrificial layer;
a third sub-stack on the second sub-stack and comprising a channel layer providing a bottommost layer of the third sub-stack and a first sacrificial layer on the channel layer,
wherein the first sacrificial layers are formed of a first sacrificial semiconductor material, the second sacrificial layers are formed of a second sacrificial semiconductor material different from the first sacrificial semiconductor material, and the liner layers are formed of a semiconductor material different from the first and second sacrificial semiconductor materials;
forming source/drain recesses, the source/drain recesses exposing end surfaces of the layer stack;
forming recesses in the first sacrificial layers of the layer stack by laterally etching back the end surfaces of the first sacrificial layers from opposite ends of the layer stack by selective etching;
removing the at least one second sacrificial layer of the second sub-stack by selective etching, thereby forming at least one cavity, while the first sacrificial layers of the second sub-stack are being protected from vertical etching by the liner layers;
depositing dielectric material in the at least one cavity; and
depositing dielectric material in the recesses of the first sacrificial layers,
wherein at least one of the acts of depositing dielectric material in the at least one cavity; and depositing dielectric material in the recesses of the first sacrificial layers, is performed by a first chemical vapor deposition method, CVD method, the first CVD method comprising:
reacting, as a film-forming gas, an oxygen-containing silicon compound gas with a non-oxidizing hydrogen-containing gas in a state in which at least the non-oxidizing hydrogen-containing gas is plasmarized, to form a film of a flowable silanol compound; and
subsequently, annealing the film of flowable silanol compound into the first dielectric material,
wherein the oxygen-containing silicon compound gas comprises Si_{α}O_{β}(O—CₘHₙ)_{Γ}CₓH_{y}, wherein m, n, and α are integers of 1 or more, and wherein β, Γ, x, and y are integers of 0 or more, and wherein β and Γ are not 0 at the same time.

2. The method according to claim 1, wherein depositing dielectric material in the at least one cavity is performed by the first CVD method.

3. The method according to claim 1, wherein depositing dielectric material in the at least one cavity and depositing dielectric material in the recesses of the first sacrificial layers are performed by the first chemical vapor deposition method.

4. The method according to claim 3, wherein depositing dielectric material in the at least one cavity and depositing dielectric material in the recesses of the first sacrificial layers are performed simultaneously.

5. The method according to claim 1, wherein a material of the channel layers is Si₁₋ₐGeₐ, a material of the liner layers is Si_{1-b}Ge_{b}, the first sacrificial semiconductor material is Si_{1-c}Ge_{c}, and the second sacrificial semiconductor material is Si_{1-d}Ge_{d}, wherein 0 S a≤b<c<d.

6. The method according to claim 5, wherein c is in a range of 0.1-0.25.

7. The method according to claim 5, wherein d is in a range of 0.35-0.5.

8. The method according to claim 5, wherein b is below 0.05.

9. The method according to claim 1, wherein the dielectric material deposited by the first CVD method comprises SiOC.

10. The method according to claim 1, wherein the dielectric material deposited by the first CVD method comprises SiOCN.

11. The method according to claim 1, wherein forming recesses in the first sacrificial layers of the layer stack is performed before removing the at least one second sacrificial layer of the second sub-stack.

12. The method according to claim 9, wherein forming recesses in the first sacrificial layers of the layer stack is performed using a first selective etch being selective to material of the channel layers and material of the liner layers but not to the first and second sacrificial semiconductor material.

13. The method according to claim 1, wherein removing the at least one second sacrificial layer of the second sub-stack is performed using a second selective etch being selective to material of the channel layers, material of the liner layers, and the first sacrificial semiconductor material.

14. The method according to claim 1, wherein a thickness of the liner layers is in a range of 1 nm to 5 nm.

15. The method according to claim 1, wherein forming the recesses comprises isotropic selective etching of the end surfaces of the first sacrificial layers from opposite ends of the layer stack.

16. The method according to claim 1, the method further comprising forming a sacrificial gate structure extending across the layer stack.

17. The method according to claim 16, wherein the sacrificial gate structure comprises a sacrificial gate body and a first spacer on opposite sides of the sacrificial gate body.

18. The method according to claim 17, wherein the source/drain recesses are formed by etching through the layer stack of the device while using the sacrificial gate structure as an etch mask such that portions of the first, second, and third sub-stacks of the layer stack are preserved underneath the sacrificial gate structure.

19. The method according to claim 1, further comprising forming source and drain regions by epitaxially growing semiconductor material on channel layer end surfaces exposed in the source/drain recesses.

20. The method according to claim 13, wherein removing the at least one second sacrificial layer of the second sub-stack is performed using a second selective etch that is not selective to the second sacrificial semiconductor material.
